(19) United States
(12) Patent Application Publication
(10) Pub. No.: US 2025/0265168 A1
(43) Pub. Date: Aug. 21, 2025

(54) PLUG-AND-PLAY HARDWARE-IN-THE-LOOP TEST BENCH FOR AUTONOMOUS VEHICLE DEVELOPMENT

(71) Applicant: Toyota Jidosha Kabushiki Kaisha, Toyota-shi Aichi-ken (JP)

(72) Inventors: Divya Garikapati, San Jose, CA (US); Yiting Liu, Dublin, CA (US); Matthew J. Brown, Palo Alto, CA (US); Tristan Robert Littlehale, San Jose, CA (US); Hirofumi Yamamoto, Cupertino, CA (US); Chen Bao, Newark, CA (US)

(21) Appl. No.: 18/655,703

(22) Filed: May 6, 2024

Related U.S. Application Data
(60) Provisional application No. 63/555,707, filed on Feb. 20, 2024.

(51) Int. Cl. G06F 11/34; G01M 17/007

(52) U.S. Cl. CPC G06F 11/3457; G01M 17/007

(57) ABSTRACT

Systems and methods described herein relate to using multimodal foundation models. In one embodiment, a method includes providing a vehicular testbench capable of operating physical and virtual vehicular components, receiving a test plan for a set of vehicular components, determining testbench components and testbench connections including any virtual components to implement the test plan on the vehicular testbench, generating the virtual components to perform the test plan, and implementing the testbench connections to enable testing of the vehicular components.

### CROSS-REFERENCE TO RELATED APPLICATIONS

The present application claims priority to U.S. Prov. App. No. 63/555,707, filed Feb. 20, 2024. The above application is hereby incorporated herein by reference in its entirety and is to be considered a part of this specification. Any and all priority claims identified in the Application Data Sheet, or any correction thereto, are hereby incorporated by reference under 37 CFR 1.57.

### TECHNICAL FIELD

The subject matter described herein relates, in general, to strategies for autonomous vehicle testing that may involve the need to test multiple components.

### BACKGROUND

With respect to the development of autonomous vehicles, it is beneficial to be able to provide testing of autonomous functions with respect to vehicle hardware prior to releasing those functions to the public. One approach used for validating vehicle hardware is to simulate the behavior of a virtual vehicle under autonomous control in a virtual environment. However, virtual environments are limited in the information they can encompass for testing and important edge cases may be missed if testing of autonomous functions relies solely on virtual representations. In addition, the use of virtual vehicles or environments may present idealized representations of vehicle behavior, such that real-world behavior of a vehicle under autonomous control is not fully tested.

### SUMMARY

In one embodiment, a system is disclosed. The system includes one or more processors and a memory communicably coupled to the one or more processors. The memory stores a command module including instructions that when executed by the one or more processors cause the one or more processors to provide a vehicular testbench capable of operating physical and virtual vehicular components, receive a test plan for a set of vehicular components, determine testbench components and testbench connections including any virtual components to implement the test plan on the vehicular testbench, generate the virtual components to perform the test plan, and implement the testbench connections to enable testing of the vehicular components.

In one embodiment, a non-transitory computer-readable medium including instructions that when executed by one or more processors cause the one or more processors to perform one or more functions is disclosed. The instructions include instructions to provide a vehicular testbench capable of operating physical and virtual vehicular components, receive a test plan for a set of vehicular components, determine testbench components and testbench connections including any virtual components to implement the test plan on the vehicular testbench, generate the virtual components to perform the test plan, and implement the testbench connections to enable testing of the vehicular components.

In one embodiment, a method is disclosed. In one embodiment, the method includes providing a testbench capable of providing a vehicular testbench capable of operating physical and virtual vehicular components, receiving a test plan for a set of vehicular components, determining testbench components and testbench connections including any virtual components to implement the test plan on the vehicular testbench, generating the virtual components to perform the test plan; and implementing the testbench connections to enable testing of the vehicular components.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of an autonomous driving system that is associated with multimodal foundation models.

FIG. 3 illustrates one embodiment of a cloud computing environment within which the systems and methods described herein may operate.

FIG. 4 illustrates one embodiment of a autonomous driving test bench.

FIG. 5 illustrates one embodiment of a vehicular interface component.

FIG. 6 illustrates one embodiment of a vehicular environment simulator.

FIG. 7A illustrates one embodiment of a autonomous driving software stack.

FIG. 7B illustrates one example of a state transition diagram of three different states of operation that may be implemented by a safety controller.

FIG. 8 illustrates one embodiment of a HMI hardware component.

FIG. 9 illustrates one embodiment of a left-hand side component.

FIG. 10 illustrates one embodiment of a right-hand side component.

FIG. 11 illustrates one example of virtual representation of a vehicle in a test environment.

FIG. 12 illustrates one example of a method for autonomous vehicle testing that may involve both a driver under test and a safety trained driver.

FIG. 13 illustrates one example of a method for handling vehicle control with respect to an implementation having both a driver under test and a safety trained driver.

FIG. 14 illustrates one example of a method for handling multiple instances of production components, prototype components, and virtual components during testing.

### DETAILED DESCRIPTION

Systems, methods, and other embodiments associated with a hardware-in-the-loop testbench with dual-cockpit driver support for testing autonomous functions are described herein. With respect to prior approaches, various methods, including hardware-in-the-loop (HIL), software-in-the-loop (SIL), model-in-the-loop (MIL), simulator-in-the-loop (SimIL), process-in-the-loop (PIL), human-in-the-loop (HuIL), etc., have been attempted to resolve issues of verification and validation with respect to autonomous functions. However, these various approaches by themselves have been insufficient to effectively present real-world scenarios for testing a driver under test (DUT), a trained safety driver (TSD), and an autonomous system (Guardian) operating at the same time within a shared vehicular environment. For example, in such an environment various control inputs in a drive-by-wire vehicular environment may be blended (e.g., combined via weighting), such as to allow smooth and predictable transitions between a DUT, TSD, or Guardian. In addition, these various approaches have not addressed the need of a testbed to be capable of highly adaptive testing of different vehicle components to test various combination of systems from different suppliers.

A testbench utilizing a dual-cockpit design offers an advantage over prior test bench approaches in that it allows for a TSD who can monitor the DUT and correct any mistakes made by the DUT, the Guardian, or both while a vehicle is being driven. In this manner, as autonomous functions mature during development, the TSD may: (i) perform corrections that the Guardian is insufficiently trained to perform; and (ii) also correct any mistakes in the Guardian's training, both of which may then be iteratively incorporated into the further training of the autonomous functions.

Furthermore, it is important to able to provide autonomous function testing at all stages of development with respect to a vehicle. As such, the testbench presented herein may test autonomous functions on virtual components (e.g., a proposed model of a braking system), prototype components (e.g., a prototype braking system), and production components (e.g., a production braking system), or a combination thereof in actual or virtual environments.

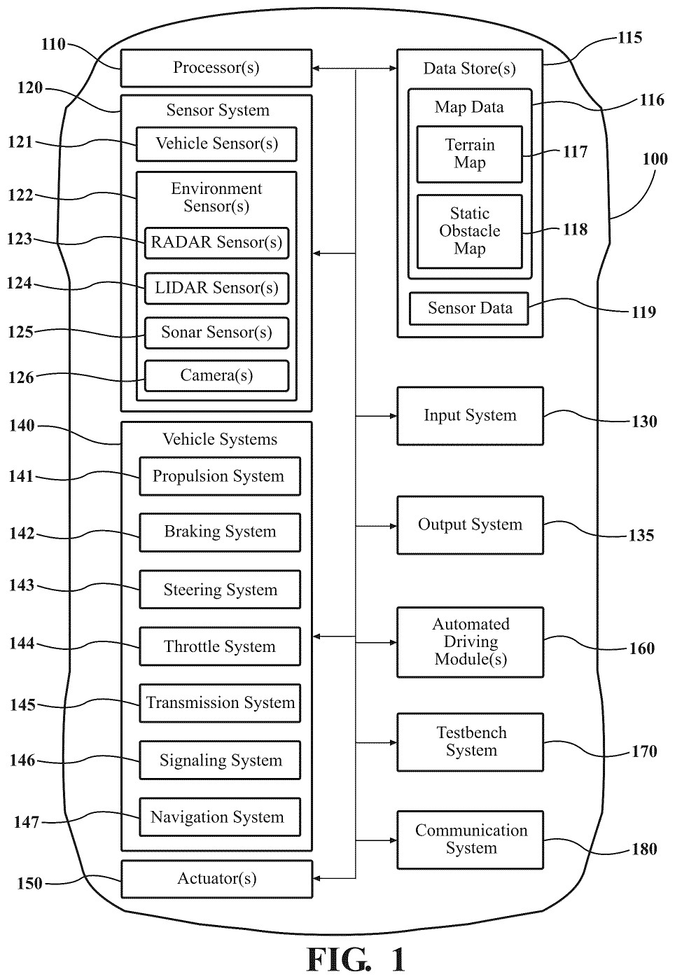

Referring to FIG. 1, an example of a vehicle 100 is illustrated. As used herein, a “vehicle” is any form of motorized transport. In one or more implementations, vehicle 100 is an automobile. While arrangements will be described herein with respect to automobiles, it will be understood that embodiments are not limited to automobiles. In some implementations, vehicle 100 may be any robotic device or form of motorized transport that, for example, includes sensors to perceive aspects of the surrounding environment, and thus benefits from the functionality discussed herein associated with strategies for autonomous vehicle testing that may involve both a driver under test and a safety trained driver. As a further note, this disclosure generally discusses vehicle 100 as a vehicle that be able to travel on a roadway with surrounding vehicles, which are intended to be construed in a similar manner as vehicle 100 itself. That is, the surrounding vehicles may include any vehicle that may be encountered on a roadway by vehicle 100.

Vehicle 100 also includes various elements. It will be understood that in various embodiments it may not be necessary for vehicle 100 to have all of the elements shown in FIG. 1. Vehicle 100 may have any combination of the various elements shown in FIG. 1. Further, vehicle 100 may have additional elements to those shown in FIG. 1. In some arrangements, vehicle 100 may be implemented without one or more of the elements shown in FIG. 1. While the various elements are shown as being located within vehicle 100 in FIG. 1, it will be understood that one or more of these elements may be located external to vehicle 100. Further, the elements shown may be physically separated by large distances. For example, as discussed, one or more components of the disclosed system may be implemented within a vehicle while further components of the system are implemented within a cloud-computing environment or other system that is remote from vehicle 100.

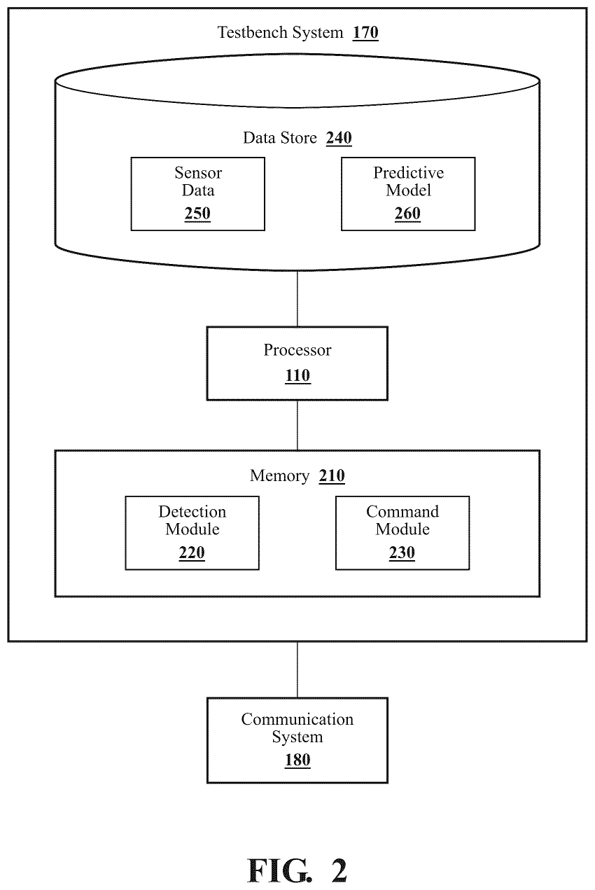

Some of the possible elements of vehicle 100 are shown in FIG. 1 and will be described along with subsequent figures. However, a description of many of the elements in FIG. 1 will be provided after the discussion of FIGS. 2-12 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, vehicle 100 includes a testbench system 170 that is implemented to perform methods and other functions as disclosed herein. As will be discussed in greater detail subsequently, testbench system 170, in various embodiments, is implemented partially within vehicle 100 and as a cloud-based service. For example, in one approach, functionality associated with at least one module of testbench system 170 is implemented within vehicle 100 while further functionality is implemented within a cloud-based computing system.

With reference to FIG. 2, one embodiment of testbench system 170 of FIG. 1 is further illustrated. Testbench system 170 is shown as including processor(s) 110 from vehicle 100 of FIG. 1. Accordingly, processor(s) 110 may be a part of testbench system 170, testbench system 170 may include a separate processor from processor 110(s) of vehicle 100, or testbench system 170 may access processor 110(s) through a data bus or another communication path. In one embodiment, testbench system 170 includes memory 210, which stores detection module 220 and command module 230. Memory 210 is a random-access memory (RAM), read-only memory (ROM), a hard-disk drive, a flash memory, or other suitable memory for storing detection module 220 and command module 230. Detection module 220 and command module 230 are, for example, computer-readable instructions that when executed by processor(s) 110 cause processor(s) 110 to perform the various functions disclosed herein.

Testbench system 170 as illustrated in FIG. 2 is generally an abstracted form of testbench system 170 as may be implemented between vehicle 100 and a cloud-computing environment. Accordingly, testbench system 170 may be embodied at least in part within a cloud-computing environment to perform the methods described herein.

With reference to FIG. 2, detection module 220 generally includes instructions that function to control processor(s) 110 to receive data inputs from one or more sensors of vehicle 100. The inputs are, in one embodiment, observations of one or more objects in an environment proximate to vehicle 100, other aspects about the surroundings, or both. As provided for herein, detection module 220, in one embodiment, acquires sensor data 250 that includes at least camera images. In further arrangements, detection module 220 acquires sensor data 250 from further sensors such as radar 123, LiDAR 124, and other sensors as may be suitable for identifying vehicles, locations of the vehicles, lane markers, crosswalks, traffic signs, vehicle parking areas, road surface types, curbs, vehicle barriers, and so on.

Accordingly, detection module 220, in one embodiment, controls the respective sensors to provide sensor data 250. Additionally, while detection module 220 is discussed as controlling the various sensors to provide sensor data 250, in one or more embodiments, detection module 220 may employ other techniques to acquire sensor data 250 that are either active or passive. For example, detection module 220 may passively sniff sensor data 250 from a stream of electronic information provided by the various sensors to further components within vehicle 100. Moreover, detection module 220 may undertake various approaches to fuse data from multiple sensors when providing sensor data 250, from sensor data acquired over a wireless communication link (e.g., v2v) from one or more of the surrounding vehicles, or from a combination thereof. Thus, sensor data 250, in one embodiment, represents a combination of perceptions acquired from multiple sensors.

In addition to locations of surrounding vehicles, sensor data 250 may also include, for example, odometry information, GPS data, or other location data. Moreover, detection module 220, in one embodiment, controls the sensors to acquire sensor data about an area that encompasses 360 degrees about vehicle 100, which may then be stored in sensor data 250. In some embodiments, such area sensor data may be used to provide a comprehensive assessment of the surrounding environment around vehicle 100. Of course, in alternative embodiments, detection module 220 may acquire the sensor data about a forward direction alone when, for example, vehicle 100 is not equipped with further sensors to include additional regions about the vehicle or the additional regions are not scanned due to other reasons (e.g., unnecessary due to known current conditions).

Moreover, in one embodiment, testbench system 170 includes a database 240. Database 240 is, in one embodiment, an electronic data structure stored in memory 210 or another data store and that is configured with routines that may be executed by processor(s) 110 for analyzing stored data, providing stored data, organizing stored data, and so on. Thus, in one embodiment, database 240 stores data used by the detection module 220 and command module 230 in executing various functions. In one embodiment, database 240 includes sensor data 250 along with, for example, metadata that characterize various aspects of sensor data 250. For example, the metadata may include location coordinates (e.g., longitude and latitude), relative map coordinates or tile identifiers, time/date stamps from when separate sensor data 250 was generated, and so on.

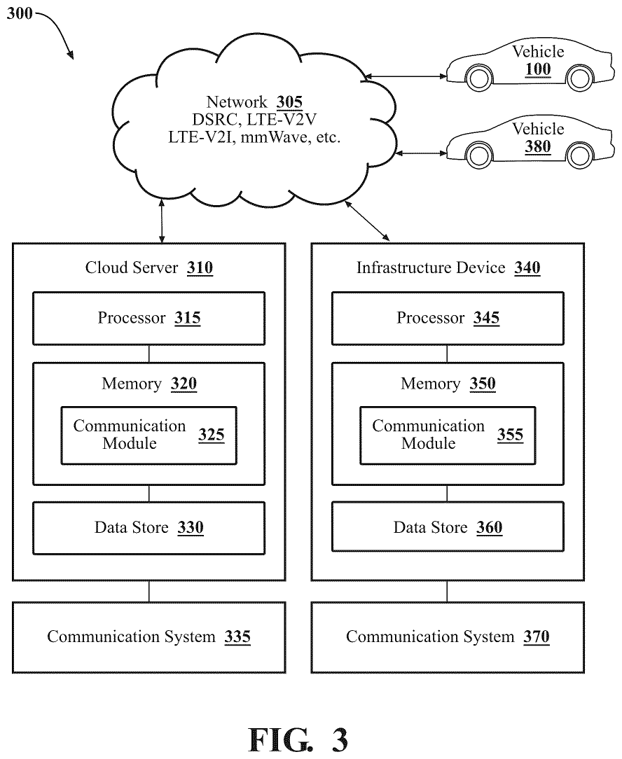

In one embodiment, command module 230 generally includes instructions that function to control the processor(s) 110 or collection of processors in the cloud-computing environment 300 as shown in FIG. 3.

With reference to FIG. 3, vehicle 100 may be connected to a network 305, which allows for communication between vehicle 100 and cloud servers (e.g., cloud server 310), infrastructure devices (e.g., infrastructure device 340), other vehicles (e.g., vehicle 380), and any other systems connected to network 305. With respect to network 305, such a network may use any form of communication or networking to exchange data, including but not limited to the Internet, Directed Short Range Communication (DSRC) service, LTE, 5G, millimeter wave (mmWave) communications, and so on.

Cloud server 310 is shown as including a processor 315 that may be a part of testbench system 170 through network 305 via communication unit 335. In one embodiment, cloud server 310 includes a memory 320 that stores a communication module 325. Memory 320 is a random-access memory (RAM), read-only memory (ROM), a hard-disk drive, a flash memory, or other suitable memory for storing communication module 325. Communication module 325 is, for example, computer-readable instructions that when executed by processor 315 causes processor 315 to perform the various functions disclosed herein. Moreover, in one embodiment, cloud server 310 includes database 330. Database 330 is, in one embodiment, an electronic data structure stored in a memory 320 or another data store and that is configured with routines that may be executed by processor 315 for analyzing stored data, providing stored data, organizing stored data, and so on.

Infrastructure device 340 is shown as including a processor 345 that may be a part of testbench system 170 through network 305 via communication unit 370. In one embodiment, infrastructure device 340 includes a memory 350 that stores a communication module 355. Memory 350 is a random-access memory (RAM), read-only memory (ROM), a hard-disk drive, a flash memory, or other suitable memory for storing communication module 355. Communication module 355 is, for example, computer-readable instructions that when executed by processor 345 causes processor 345 to perform the various functions disclosed herein. Moreover, in one embodiment, infrastructure device 340 includes a database 360. Database 360 is, in one embodiment, an electronic data structure stored in memory 350 or another data store and that is configured with routines that may be executed by processor 345 for analyzing stored data, providing stored data, organizing stored data, and so on.

Accordingly, in addition to information obtained from sensor data 250, testbench system 170 may obtain information from cloud servers (e.g., cloud server 310), infrastructure devices (e.g., infrastructure device 340), other vehicles (e.g., vehicle 380), and any other systems connected to network 305. For example, cloud servers (e.g., cloud server 310) may be used to perform the same tasks as described herein with respect to command module 230.

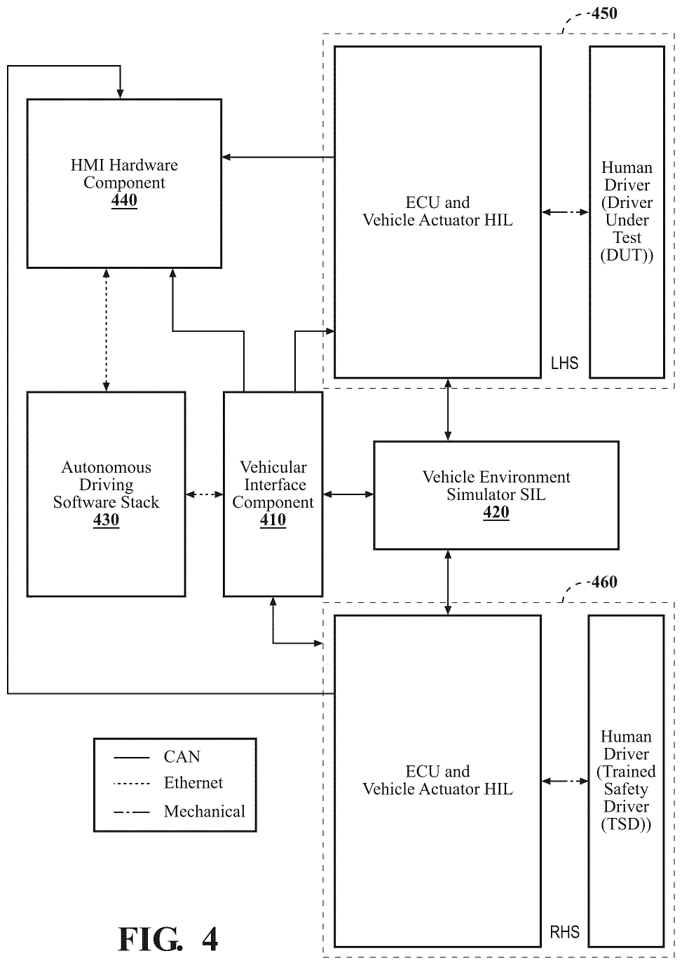

FIG. 4 illustrates an example of autonomous driving test bench 400 that may be implemented via vehicle 100 using testbench system 170. Autonomous driving test bench 400 may be comprised of a vehicular interface component 410, vehicular environment simulator 420, an autonomous driving software stack 430, an HMI hardware component 440, a left-hand side (LHS) component 450, and a right-hand side (RHS) component 460. These components may be coupled directly or indirectly with each other so as to facilitate electronic communication between the various components of autonomous driving test bench 400. For example, as shown in FIG. 4, vehicular interface component 410 may be coupled by a CAN bus so as to exchange messages with vehicular environment simulator 420, HMI hardware component 440, LHS component 450, and RHS component 460. In addition, vehicular interface component 410 may be coupled by Ethernet so as to exchange messages with autonomous driving software stack 430. Ethernet may also be used to connect the autonomous driving software stack 430 with HMI hardware component 440. Similarly, a CAN bus may also be used to connect both LHS component 450 and RHS component 460 to both vehicular environment simulator 420 and HMI hardware component 440. In various embodiments, other forms of connectivity may be used instead of or in addition to what is shown in FIG. 4. For example, a CAN bus may be replaced by an Ethernet network; one or more gateways may be implemented to allow CAN bus messages to be sent over Ethernet; wired connections may be replaced with wireless or optical connections; other protocols other than Ethernet may be used; and so on.

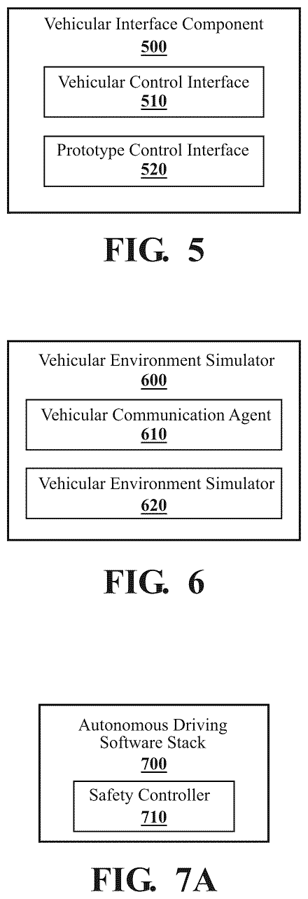

With respect to FIG. 5, an example of a vehicular interface component 500 is shown, which may be used to provide vehicular interface component 410 as described above. Vehicular interface component 500 may be comprised of a vehicular control interface 510 and a prototype control interface 520. Vehicular control interface 510 may be configured to operate a vehicle (e.g., vehicle 100) or a portion thereof (e.g., production components). Prototype control interface 520 may be configured to operate one or more prototype hardware components, which may be fully or only partially integrated within the vehicle (or a portion thereof).

For example, vehicular control interface 510 may provide all the vehicle functions of vehicle 100 except for a steering system, while prototype control interface 520 may provide the vehicle functions of a prototype steering system that interacts with vehicle 100. In this manner, the prototype steering system provided by the prototype control interface 520 may be configured to act as the steering system for vehicle 100.

In some embodiments, prototype control interface 520 may configure the prototype steering system as the steering system of vehicle 100 by instructing vehicle 100 to send all messages that would be received by a default steering system of vehicle 100 to the prototype steering system. In addition, prototype control interface 520 may be configured to provide any functionality required to enable the operation of the one or more prototype hardware components that vehicular control interface 510 may not be able to provide (e.g., operating of a cooling system for the prototype hardware component that vehicular control interface 510 was not designed to support).

With respect to FIG. 6, an example of a vehicular environment simulator 600 is shown, which may be used to provide vehicular environment simulator 420 as described above. Vehicular environment simulator 600 may be comprised of vehicular communication agent 610 and vehicular environment simulator 620. Vehicular communication agent 610 may operate to enable one or more vehicle-based communication protocols (e.g., a vehicle CAN bus agent, Ethernet), so as to support the interconnection of hardware and software components within the testbench (e.g., autonomous driving test bench 400). For example, vehicular communication agent 610 may provide vehicle-based communication functionality to support different vehicle types, such as hybrid vehicles, internal combustion engine vehicles, electric vehicles, or others, such that production components, prototype components, or simulation components may operate with each other. For instance, vehicular communication agent 610 may mimic the connections of several CAN buses simultaneously. Vehicular communication agent 610 may also translate messages such that production components, prototype components, or simulation components may seamlessly communicate with each other even if they have incompatible communication protocols (e.g., translating CAN buses messages from a component into Ethernet messages that can be received by another component and vice versa). Vehicular communication agent 610 may also duplicate messages, such as where multiple instances of production components, prototype components, or simulation components are to be tested. For example, vehicular communication agent 610 may duplicate braking control inputs from LHS component 900 such that one or more braking vehicle components, one or more braking prototype components, one or more braking virtual components, or a combination thereof are all operated by the same braking control inputs messages. In some embodiments, vehicular communication agent 610 may when duplicating messages also act to adjust the timing of duplicate messages, thereby allowing for multiple instances of production components, prototype components, or simulation components to operate in a synchronous fashion (or alternatively, in an offset arrangement if so desired).

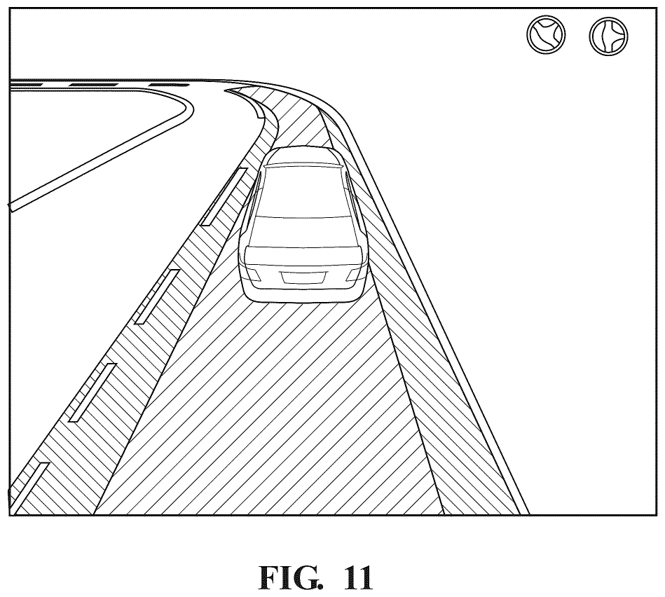

Vehicular environment simulator 620 may act to provide simulation and evaluation functions based on information received from any of the production components, prototype components, or simulation components. For example, as shown in FIG. 11, the information gathered by vehicular environment simulator 620 may be used to model a virtual representation of a vehicle in a test environment. Vehicular environment simulator 620 may also be able to evaluate the performance of the virtual vehicle in the virtual environment, such as the impact of different vehicle controls in extreme driving scenarios (e.g., high speed driving, loss of signals, unstable communications, unexpected events). Vehicular environment simulator 620 may also compare its evaluations with data obtained from outside of the testbench (e.g., from external sensors on a test track) and may also allow for adjustment of such evaluations based on such comparisons.

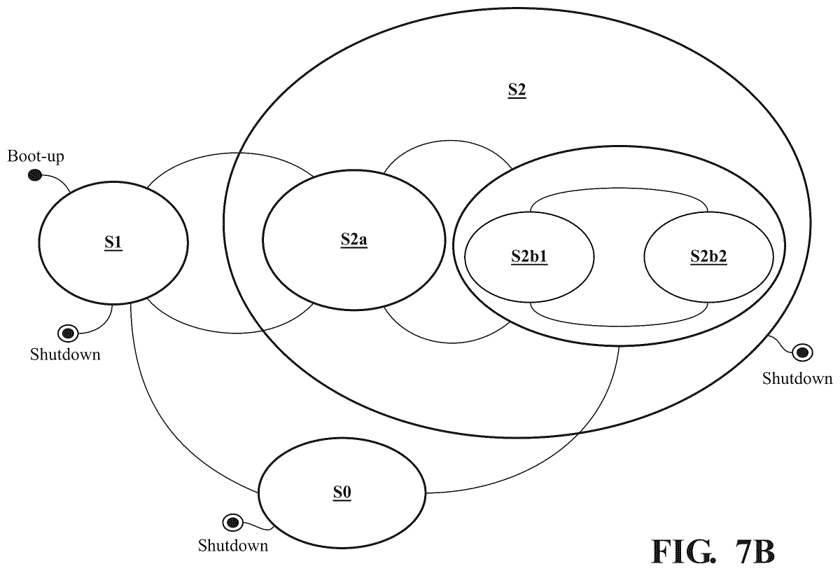

With respect to FIG. 7, an example of an autonomous driving software stack 700 is shown, which may be used to provide autonomous driving software stack 430 as described above. Autonomous driving software stack 700 may provide any semi-autonomous or autonomous functionality as described herein, including simulating scenarios and executing perception, planning, and control functions. Autonomous driving software stack 700 may also contain safety controller 710. Safety controller 710 may serve to implement different states of operation, where each state of operation may specify how a vehicle (e.g., vehicle 100) is controlled between the LHS component 900, RHS component 1000, autonomous driving software stack 700, other sources of control inputs, or a combination thereof. For example, FIG. 7B shows a state transition diagram of three different states of operation that may be implemented by safety controller 710. In such an example, safety controller 710 has provided three different states of operation.

In state of operation S1, which may be the default state, safety controller 710 may configure the testbench such that the vehicle operates solely under the control of the LHS component 900 (e.g., as if it were a traditional vehicle).

In state of operation S2, which may be the testing state, safety controller 710 may configure the testbench such that the vehicle operates within sub-state S2a, S2b1, or S2b2.

In sub-state S2a, the vehicle may operate solely under the control of the RHS component 1000. In some embodiments, sub-state S2a may allow for joint control by LHS component 900 and RHS component 1000, which may also further include the requirement that RHS component 1000 overrides LHS component 900 with respect to vehicle control if there is a difference between the two.

In sub-state S2b1, the vehicle may operate solely under the control of autonomous driving software stack 700. In some embodiments, sub-state S2b1 may allow for LHS component 900, RHS component 1000, or both to provide control inputs to autonomous driving software stack 700, which may then be evaluated by autonomous driving software stack 700 in its determination of control inputs for the vehicle.

In sub-state S2b2, the vehicle may operate as above with respect to sub-state S2b1 except that when a guardian interrupt mode (described below) is activated then RHS component 1000 may fully or partially override autonomous driving software stack 700, LHS component 900, or both. For example, a first guardian interrupt mode activation may cause a state of operation requiring that the RHS component 1000 may override autonomous driving software stack 700, LHS component 900, or both until such time as the guardian interrupt becomes inactive. As another example, a second guardian interrupt mode activation may cause a state of operation requiring that steering and throttle control adjustments made by RHS component 1000 are implemented, but still allow for autonomous driving software stack 700, LHS component 900, or both to influence braking control if no contrary input has been received from the RHS component 1000.

In state of operation S0, which may be the emergency state, the vehicle may operate to shutdown safely, such as by slowing to a stop and coming to a halt by the side of the road; disengaging throttle; etc. State S0 may be a state that is required by safety controller 710 to be reachable from any other state if pre-determined conditions are met (e.g., vital system failure). In such an embodiment, states of operation that prevent a vehicle from reaching an emergency state when the pre-determined conditions are met may be rejected by safety controller 710 as invalid.

Safety controller 710, based on states of operation, may determine the extent that one or more components (e.g., autonomous driving software stack 700, LHS component 900, RHS component 1000) are allowed to operate the vehicle. As such, safety controller 710 may allow for individual control or joint control between the LHS component 900, RHS component 1000, or autonomous driving software stack 700 as determined by each state of operation. Where a state of operation specifies joint control, the state of operation may determine which control inputs take priority (e.g., autonomous driving software stack 700 always overrides LHS component 900 and RHS component 1000). In some embodiments, priority may be determined by weighting of the control inputs. For example, a state of operation may specify that the control signals from RHS component 1000 have twice as much impact as control signals from LHS component 900. As another example, a state of operation may utilize a weighting function to be applied to one or more control inputs of the same type to form a combined control of that type.

In some embodiments, safety controller 710 may establish concurrency rules with respect to the visible state of control input devices. For example, a simple concurrency rule is that the steering wheel of the RHS component 1000 and the steering wheel of the LHS component 900 shall be positioned the same with respect to the steering control inputs (e.g., if RHS component 1000 is generating control inputs, then have LHS component 900 adjust to reflect such control inputs, or vice versa) or steering feedback (e.g., feedback signals from a steering system within vehicle 100). In this manner, the steering wheels may seem to appear to act the same due to driving inputs made by either driver, both drivers, autonomous driving software stack 700, etc. In some embodiments, the positioning of control input devices may be specified by a combined control input (e.g., created by a weighting function).

As another example, in a state of operation where the RHS component 1000 and LHS component 900 can jointly operate the vehicle and the LHS component 900 can override the RHS component 1000, the concurrency rule may require: (i) that the control input devices of RHS component 1000 mimic the control input devices of LHS component 900 if driving inputs are not being made to control input devices of RHS component 1000; and (ii) that control input devices of LHS component 900 always mimic the control input devices of RHS component 1000 if driving inputs are being made to control input devices of RHS component 1000. In this manner, the control input devices of RHS component 1000 may reflect the actions of a first driver who is primarily operating the vehicle through the control input devices of LHS component 900, except where a second driver uses the control input devices of RHS component 1000 to takeover control from the first driver.

In some embodiments, safety controller 710 may also establish transition rules for handling changes between states of operations involving different concurrency rules. For example, if safety controller 710 transitions from a state of operation allowing LHS component 900 control only to a state of operation allowing joint control by the LHS component 900 or RHS component 1000, a transition rule may specify a ramping function to be applied to the implementation of that state of operation's concurrency rule by safety controller 710, which may provide a smoother appearance of transitions to a driver when changes in states of operation occurs. In some embodiments, such a transitional rule may not only be aesthetically pleasing in result but also may provide safety benefits by limiting sudden changes that could startle or injure a driver due to the sudden implementation of a concurrency rule. In some embodiments, the transition rule may only affect how the implementation of a concurrency rule affects the physical position of control input devices of the LHS component 900 or RHS component 1000. For example, even if it is desirable to provide a smoother appearance of transitions as described above, entry into a state of operation may nonetheless require immediate implementation of a concurrency rule except as to the physical position of control devices. Such transition rules may be implemented, for instance, where entry into a new state of operation causes autonomous driving software stack 700 to execute a critical and extreme maneuver for safety purposes.

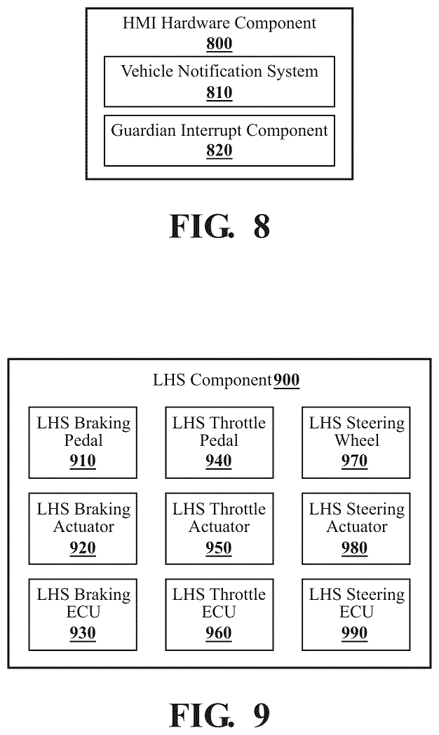

With respect to FIG. 8, an example of an HMI hardware component 800 is shown. HMI hardware component 800 may be comprised of a vehicle notification system 810, a guardian interrupt component 820 (e.g., a pedal that may be actuated by a safety driver to take full control of a vehicle), or other HMI components not provided for by LHS component 900 or RHS component 1000 as described below.

Vehicle notification system 810 may provide support for any audio, visual, haptic, or other type of alert or indicator that may be used to communicate with a vehicle operator. For example, vehicle notification system 810 may utilize visual indicators (e.g., colored LEDs), audio indicators (e.g., different tones, voice announcements), vibration, and so on to indicate the health of system components or the system overall; the state of operation of the vehicle (e.g., Manual, Autonomous Active); the activation of a guardian interrupt mode; which driver is controlling the vehicle (e.g., DUT, TSD, Guardian); emergency vehicle operation; and so on.

In some embodiments, vehicle notification system 810 may utilize HMI rules to facilitate the translation of HMI messages. For example, different displays, steering wheels, or other HMI components may be utilized within the testbench, each with different HMI interfaces. Accordingly, vehicle notification system 810 may store and utilize HMI rules that allow for HMI to be implemented between the testbench and one or more HMI devices. In some embodiments, if a new component is added to the testbench, vehicle notification system 810 may detect the change in available HMI interfaces, locate one or more HMI rules based on that detection, and then implement the one or more HMI rules. Similarly, if a component is removed from the testbench, vehicle notification system 810 may detect such a change with respect to HMI interfaces and cease using any HMI rules no longer required.

Guardian interrupt component 820 may allow a set of input control devices (e.g., those used by a TSD via RHS component 1000) to have partial or full control of the vehicle in a manner that has priority over any other driving inputs. For example, guardian interrupt component 820 may utilize a pedal, button, voice command, or other forms of HMI interfaces to allow a driver to activate or deactivate a guardian interrupt mode.

When guardian interrupt mode is active, safety controller 710 may implement a state of operation in which one or more control signals take priority over any other control signals. For example, if a TSD operating the RHS component 1000 activates guardian mode, the steering, braking, throttle, and any other control inputs of the RHS component 1000 may take priority over any control inputs from the LHS component 900, autonomous driving software stack 700, or other sources. In some embodiments, such priority may suppress any control signals other than those authorized by the state of operation triggered by the guardian interrupt mode activation (e.g., RHS only, no LHS, no autonomous driving software stack 700). In some embodiments, such suppression may be limited to only some controls (e.g., RHS steering and throttle only, but LHS braking or autonomous driving software stack 700 control inputs may still activate braking systems).

In some embodiments, guardian interrupt component 820 may provide multiple guardian interrupt modes at different priorities. For example, LHS component 900 may have an LHS guardian interrupt pedal that allows it to suppress autonomous driving software stack 700 control inputs while RHS component 1000 may have an RHS guardian interrupt pedal that allows it to suppress LHS component 900 or autonomous driving software stack 700 control inputs.

In some embodiments, guardian interrupt interfaces may be operated by testbench users other than a DUT or TSD. For example, a track observer may engage a guardian interrupt mode via a mobile application interface in communication with the testbench that gives autonomous driving software stack 700 control inputs priority over LHS component 900 or RHS component 1000 control inputs. Such a configuration may be useful where only one driver (e.g., the DUT) is operating the testbench vehicle and the imposition of autonomous driving software stack 700 is desired to ensure the safe operation of the vehicle.

With respect to FIG. 9, an example of a LHS component 900 is shown. LHS component 900 may be comprised of any components used to generate control inputs based on the actions of a left-hand side driver. For example, LHS component 900 may utilize a LHS braking pedal 910 with a LHS braking actuator 920 and a LHS braking ECU 930 to receive braking inputs from the LHS driver and generate LHS braking control inputs. LHS component 900 may also utilize a LHS throttle pedal 940 with a LHS throttle actuator 950 and an LHS throttle ECU 960 to receive throttle inputs from the LHS driver and generate LHS throttle control inputs. Similarly, LHS component 900 may also utilize a LHS steering wheel 970 with a LHS steering actuator 980 and an LHS steering ECU 990 to receive steering inputs from the LHS driver and generate LHS steering control inputs. In some embodiments, LHS component 900 may contain other arrangements of LHS devices for generating control inputs based on the actions of a LHS driver. For example, LHS braking pedal 910, LHS braking actuator 920, and LHS braking ECU 930 may be omitted where the throttle components provide both throttle and braking functionality (e.g., single pedal driving). As another example, LHS devices used to generate control inputs based on the voice commands of a LHS driver may be added to LHS component 900.

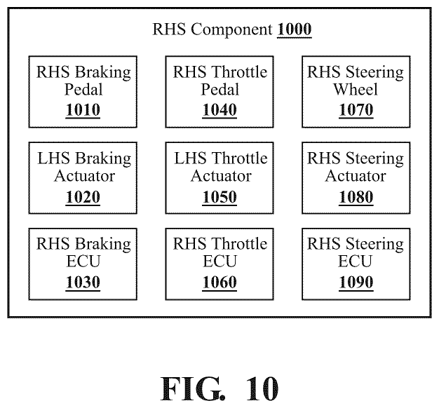

With respect to FIG. 10, an example of a RHS component 1000 is shown. RHS component 1000 may be identical in configuration to LHS component 900, except that the devices of RHS component 1000 may be used to generate RHS control inputs based on the actions of a RHS driver.

In some embodiments, the devices of RHS component 1000 may differ from that of LHS component 900. For example, LHS component 900 may utilize a prototype steering wheel while RHS component 1000 may utilize a standard production steering wheel. As another example, LHS component 900 may utilize devices used to generate LHS control inputs based on voice commands of the LHS driver, while RHS component 1000 may utilize standard production control input devices (e.g., brake, throttle, steering wheel). In addition, it should be understood even when the RHS component 1000 uses the same devices as LHS component 900, the layout of those components as between RHS component 1000 and LHS component 900 may be the same, inverted, mirrored, or otherwise arranged as desired.

While examples given herein may make reference to LHS and RHS, it should be understood that these references are merely exemplary. For example, the location of the LHS components and LHS driver may be at any location, such as within a vehicle (e.g., on the left-hand side of the vehicle, in the center of the vehicle, in the right-hand side of the vehicle, in the rear of the vehicle) or outside of a vehicle (e.g., a desk, a dual-cockpit). Similarly, the location of the RHS components and RHS driver may also be at any location. As such, any examples given herein with respect to left-hand drive vehicles should be understood to be applicable to other vehicle configurations (e.g., center-drive, right-hand drive, remotely driven).

In some embodiments, autonomous driving test bench 400 may support testing of any arrangement of one or more production components, one or more prototype components, one or more virtual components, or a combination thereof. For example, it may be desired to perform a test that compares prototype braking components against a production braking component in use and also a virtual braking component (which may for instance represent some ideal braking component). In order to perform such a test, any control signal, feedback signal, sensor signal, or other data communicated within autonomous driving test bench 400 may be duplicated. For example, braking control inputs from the autonomous driving software stack 700, LHS component 900, RHS component 1000, or a combination thereof may be duplicated so that each production braking component, prototype braking component, or virtual braking component receives the same set of braking control inputs.

In some instances, open loop testing through duplication of control inputs or other data may be sufficient to test all the components. For example, production, prototype, or virtual door locking components may be tested to determine when failure may occur for each component at extreme temperatures (e.g., by failing to lock or unlock within specified parameters), wherein testing utilizes duplication of door lock control signals and temperature sensor data. In tests involving virtual components, a virtual component may contain a deterministic or probabilistic model of how such a virtual component may degrade, fail, or otherwise perform as system test parameters change.

In some instances, closed loop testing may be required to fully test a component. For example, the output signals of a braking component may affect overall vehicle behavior in a manner that results in changes to future braking control inputs. In such a situation, autonomous driving test bench 400 may take the following approaches, among others, to test a set of production, prototype, or virtual components.

First, to the extent necessary resources for closed loop testing are available within or to autonomous driving test bench 400, the testbench may seek to create as many instances of close loop testing as possible. For example, even if autonomous driving test bench 400 has access to only one vehicle such a vehicle may have four sets of braking systems allowing for closed loop testing of up to four production, prototype, or virtual braking components at a time. In such a situation, autonomous driving test bench 400 may be provided a selection of possible closed loop testing options to a user to choose from (e.g., front brakes only, rear brakes only) so as to limit closed loop testing to specific configurations of interest.

Second, to the extent permitted by testbench settings, autonomous driving test bench 400 may seek to schedule closed loop testing for a sequence of subsets of the set of production, prototype, or virtual components according to time-based intervals. For example, closed loop testing may proceed by testing two braking components at a time until finished. In some embodiments, the testing sequence may be structured using time division multiplexing, such as where closed loop testing can be resolved before the adjustment of a system testing parameter to a new state (e.g., test all braking components at −20F before reducing the temperature to −25F).

Third, in some embodiments, autonomous driving test bench 400 may instructed to perform closed loop testing of a first subset of the set of production, prototype, or virtual components and to perform open loop testing with respect to a second subset of the set of production, prototype, or virtual components. Such an approach may be useful for example where failure in an open loop testing of a component may exclude the need for further closed loop testing.

Fourth, in some embodiments, autonomous driving test bench 400 may generate simulated feedback signals or other data such that a subset of the set of production, prototype, or virtual components unable to perform closed loop testing may nonetheless perform simulated closed loop testing. Simulated feedback signals may be implemented for example by simulating in a virtual environment how the outputs of the subset may affect vehicle operation (e.g., via vehicular environment simulator 620) to generate simulated feedback signals, simulated sensor data, or other simulated data. Such an approach may be useful for example where failure in simulated closed loop testing of a component may exclude the need for further closed loop testing of the component. In some embodiments, simulated close loop testing only need simulate those physical resources which are not sufficiently available for closed loop testing. It should also be understood that in some embodiments, closed loop testing may use virtual components (e.g., a software prototype), but unlike simulated close loop testing there is no substitution of a simulated component for a production component, prototype component, virtual component, etc.

With respect to the testbench testing described above, it should be understood that the production, prototype, or virtual components may not necessarily be located in the same vehicle or even the same city. For example, one practical aspect of autonomous driving test bench 400 is that it may allow for testing of components in remote locations. For example, if a mechanic at a dealership wishes to test if a vehicle component is still reliable, he or she access the autonomous driving test bench 400, connect the vehicle component of interest to the testbench, and then run tests via the testbench to evaluate the reliability of the component. Such an approach may be useful where reliability of a component cannot be fully determined without real-world testing in a vehicle or a vehicle sub-system. Similarly, third-party suppliers developing a prototype component may access the testbench to perform testing of one or more prototype components. In some embodiments, a vehicle (e.g., vehicle 100) residing at a location (or a portion of the vehicle) may be used as part of autonomous driving test bench 400 to remotely test components.

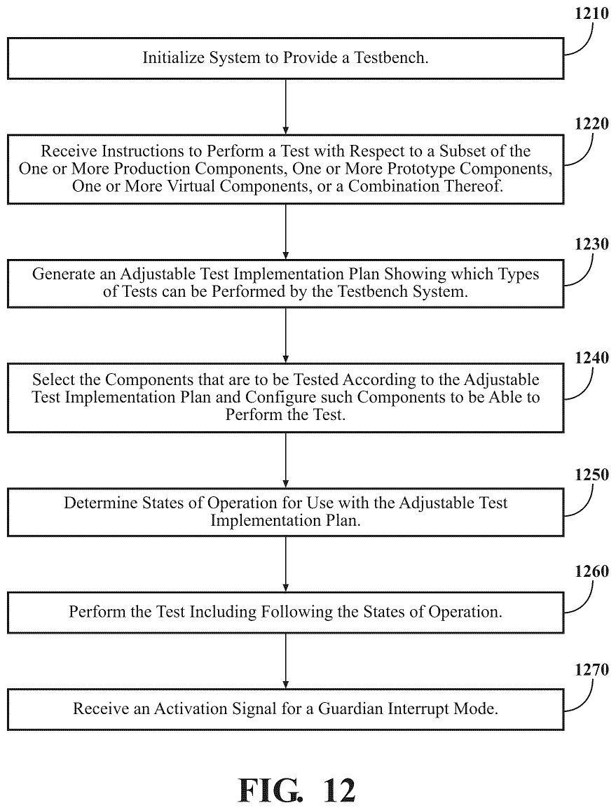

FIG. 12 illustrates a flowchart of a method 1200 that is associated with strategies for autonomous vehicle testing that may involve both a driver under test and a safety trained driver. Method 1200 will be discussed from the perspective of the testbench system 170 of FIGS. 1 and 2. While method 1200 is discussed in combination with the testbench system 170, it should be appreciated that the method 1200 is not limited to being implemented within testbench system 170 but is instead one example of a system that may implement method 1200.

At step 1210, command module 230 may initialize testbench system 170 to provide a testbench (e.g., autonomous driving test bench 400). In providing the testbench, command module 230 may configure one or more production components, one or more prototype components, one or more virtual components, or a combination thereof to communicate with testbench system 170 and also to be capable of operating as vehicle component for a test that may be run on testbench system 170. In some embodiments, command module 230 may provide this with a plug-and-play functionality, where a component added to testbench system 170 provides sufficient information to enable command module 230 to configure the component for interoperability with testbench system 170.

At step 1220, command module 230 may receive instructions to perform a test with respect to a subset of the one or more production components, one or more prototype components, one or more virtual components, or a combination thereof. Upon receiving the instructions, command module 230 may determine the testbench resources available to perform the test. For example, if closed loop testing is requested command module 230 may determine the resources available to support closed loop testing. If insufficient resources are available for closed loop testing, command module 230 may offer alternative approaches such as sequential closed loop testing (e.g., perform closed loop testing of components one after another until complete), closed loop/open loop testing (e.g., perform closed loop testing of some components, perform open loop testing for the rest), closed loop/simulated closed loop testing (e.g., virtually add resources via simulation to perform simulated closed loop testing for those components that cannot participate in closed loop testing), and so on.

At step 1230, command module 230 may generate (and present to a testbench user) an adjustable test implementation plan showing which types of tests can be performed by testbench system 170. Command module 230 may then receive instructions containing modifications, selections, or other adjustments to the adjustable test implementation plan. (e.g., selecting closed loop/simulated closed loop testing, then specifying which components should be testing using closed loop vs simulated closed loop testing).

At step 1240, command module 230 may select the one or more production components, one or more prototype components, one or more virtual components, or a combination thereof that are to be tested according to the adjustable test implementation plan and configure such components to be able to perform the test. In order to configure components to be able to perform the test, command module 230 may instruct testbench system 170 as to the arrangement of control signals, feedback signals, simulated signals, sensor data, etc. that must be communicated throughout testbench system 170. For example, command module 230 may instruct the LHS component 900 to use a prototype throttle component for disabled drivers instead of a standard production throttle component. In some embodiments, command module 230 may generate simulation components, simulation environments, or both to facilitate simulated closed loop testing as needed. In addition, instructions as to the arrangement of control signals, feedback signals, simulated signals, sensor data, etc., may include determinations as to the routing, duplicating, generating, or simulating of information or other adjustments necessary to enable the components to be tested.

At step 1250, command module 230 may determine states of operation for use with the adjustable test implementation plan. In some embodiments, the states of operation may be automatically generated based on the components being tested or used by the adjustable test implementation plan. The states of operation in some instances may also be generated based on a selection of a pre-defined template. The states of operations may also be further refined by modifications by a testbench user to the states of operation generated by the command module 230. In some embodiments, command module 230 may generate the state of operations based on the number of drivers present or the functional availability of autonomous driving software stack 700. For example, if no driver is detected to be in position to operate the RHS component 1000, states of operation may be modified by removing states that would only be utilized if RHS component 1000 would be utilized. Similarly, if autonomous driving software stack 700 lacks functionality to operate with certain aspects of a test (e.g., because a TSD will provide oversight of the vehicle until such functionality is sufficiently developed), states of operation may be modified by removing states that would only be utilized if such functionality was present. Determining the states of operation by command module 230 may also include command module 230 determining concurrency rules, transition rules, weighting functions, etc. for each state of operation. Command module 230 may also generate or modify states of operation to include criteria with respect to changes in testing or environmental data that may also cause a transition from one state of operation to another. For example, certain state of operations may be restricted based on geolocation data (e.g., for use with test track only).

At step 1260, command module 230 may perform the test including following the states of operation. In following the states of operation, command module 230 may adjust the source of control signals, the position of control devices, generate combined control signals and so on based on the control inputs of the one or more drivers, autonomous driving software stack 700, or other sources of vehicle control.

At step 1270, command module 230 may receive an activation signal for a guardian interrupt mode. Upon receiving the guardian interrupt mode, command module 230 may switch to a different state of operation based on the guardian interrupt mode activated. While the guardian interrupt mode is active, command module 230 may act to only follow certain control signals (e.g., those originating from RHS component 1000) while ignoring others (e.g., from autonomous driving software stack 700 or LHS component 900). Further, once the guardian interrupt mode is deactivated, command module 230 may change to another state of operation (e.g., the one prior to guardian interrupt mode being activated).

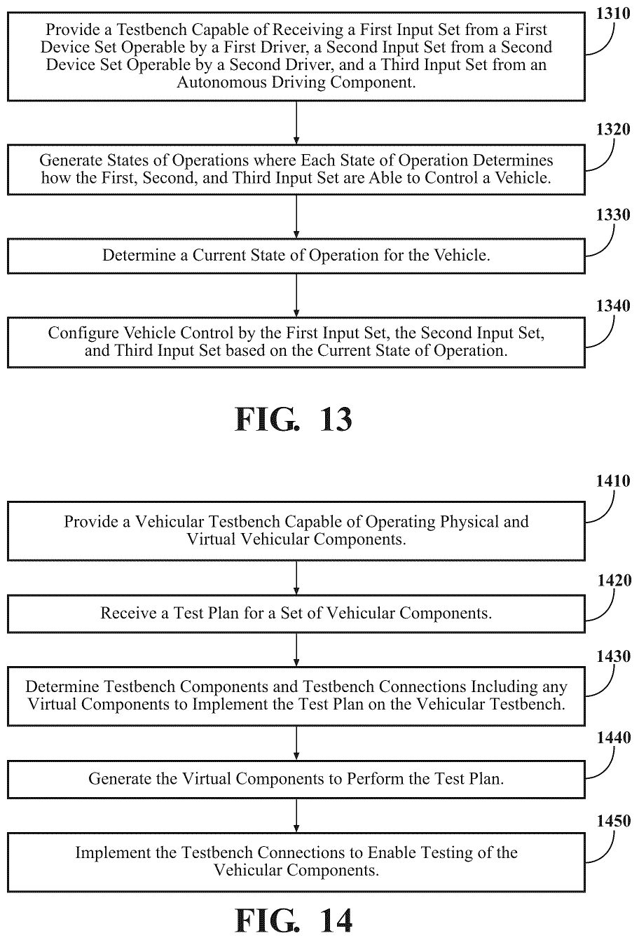

FIG. 13 illustrates a flowchart of a method 1300 that is associated with handling vehicle control with respect to an implementation having both a driver under test and a safety trained driver. Method 1300 will be discussed from the perspective of the testbench system 170 of FIGS. 1 and 2. While method 1300 is discussed in combination with the testbench system 170, it should be appreciated that the method 1300 is not limited to being implemented within testbench system 170 but is instead one example of a system that may implement method 1300.

At step 1310, command module 230 may provide a testbench capable of receiving a first input set from a first device set operable by a first driver, a second input set from a second device set operable by a second driver, and a third input set from an autonomous driving component. For example, vehicle 100 may be configured to have controls on both the left-hand and right-hand side of the forward vehicle compartment. The left-hand side may be configured for a DUT. The right-hand side may be configured for a TSD including a guardian pedal for activating a guardian interrupt mode. Testbench system 170 of vehicle 100 may be configured to provide autonomous driving test bench 400 in relation to the operation of vehicle 100 by the DUT, TSD, or an autonomous driving module.

At step 1320, command module 230 may generate states of operations where each state of operation determines how the first, second, and third input set are able to control a vehicle. For example, one state of operation may be that the left-hand side of vehicle 100 is able to drive vehicle 100 without interference from the TSD or autonomous driving module and another state of operation may be that the left-hand side of vehicle 100 is able to drive vehicle 100 subject to being overridden by the TSD or autonomous driving module.

At step 1330, command module 230 may determine a current state of operation for the vehicle. For example, based on the test being performed, environmental parameters, the behavior of the DUT, TSD, or autonomous driving module, or other factors, command module 230 may determine the particular state of operation that vehicle 100 is operating within.

At step 1340, command module 230 may configure vehicle control by the first input set, the second input set, and third input set based on the current state of operation. For example, if the vehicle changes from one state of operation, command module 230 may adjust the ability of the DUT, TSD, and autonomous driving module to control the vehicle. In addition, command module 230 may use concurrency rules or transition rules in implementing such a configuration of vehicle control.

FIG. 14 illustrates a flowchart of a method 1400 that is associated with handling multiple instances of production components, prototype components, and virtual components during testing. Method 1400 will be discussed from the perspective of the testbench system 170 of FIGS. 1 and 2. While method 1400 is discussed in combination with the testbench system 170, it should be appreciated that the method 1400 is not limited to being implemented within testbench system 170 but is instead one example of a system that may implement method 1400.

At step 1410, command module 230 may provide a vehicular testbench capable of operating physical and virtual vehicular components. For example, testbench system 170 may initialize autonomous driving test bench 400 and provide plug-and-play functionality as described herein. For example, if a prototype component is added to the testbench, command module 230 may receive an identifier electronically from the prototype component allowing it to look up how to configure the testbench to interoperate with the prototype component.

At step 1420, command module 230 may receive a test plan for a set of vehicular components. For example, a test plan may set out testing procedures, components to be tested, testing environment, testing parameters, and so on.

At step 1430, command module 230 may determine testbench components and testbench connections including any virtual components to implement the test plan on the vehicular testbench. For example, the test plan may provide sufficient information as to the components to be tested and also the closed-loop components whose use is restricted during testing (e.g., only one component may use them at a time). In some embodiments, the type of test or the component may provide sufficient information for command module 230 to determine which closed-loop components may be restricted. For example, if the type of test is of an automated driving longitudinal-based control function having different degrees of aggressiveness, command module 230 may determine that braking and throttle components should be restricted. Once restrictions are identified, command module 230 may then determine if other components are available elsewhere (e.g., at another location) or if virtual simulation can be used in substitutes. If substitutes are not available, command module 230 may analyze the test plan and suggest modifications that allow for a modified test plan to proceed. In some embodiments, the command module 230 may have settings that instruct it on how to proceed with test modifications without approval from a test bench user.

At step 1440, command module 230 may generate the virtual components to perform the test plan. For example, if command module 230 has determines that a test plan requires a virtual steering system that controls a virtual vehicle in a virtual environment, command module 230 may construct such elements for with use with the test plan.

At step 1450, command module 230 may implement the testbench connections to enable testing of the vehicular components. For example, as the command module 230 proceeds through the test plan, the components being used for closed-loop testing or other types of tests may need to change. As such, command module 230 can adjust the testbench by changing the routing of testbed signals through the test bench. For example, where a portion of a test has been completed with respect to a production throttle ECU and needs to proceed to a prototype throttle ECU, command module 230 may redirect throttle control inputs through the prototype throttle ECU instead of the production throttle ECU.

FIG. 1 will now be discussed in full detail as an example environment within which the system and methods disclosed herein may operate. In some instances, vehicle 100 is configured to switch selectively between various modes, such as an autonomous mode, one or more semi-autonomous operational modes, a manual mode, etc. Such switching may be implemented in a suitable manner, now known, or later developed. “Manual mode” means that all of or a majority of the navigation/maneuvering of the vehicle is performed according to inputs received from a user (e.g., human driver). In one or more arrangements, vehicle 100 may be a conventional vehicle that is configured to operate in only a manual mode.

In one or more embodiments, vehicle 100 is an autonomous vehicle. As used herein, “autonomous vehicle” refers to a vehicle that operates in an autonomous mode. “Autonomous mode” refers to using one or more computing systems to control vehicle 100, such as providing navigation/maneuvering of vehicle 100 along a travel route, with minimal or no input from a human driver. In one or more embodiments, vehicle 100 is either highly automated or completely automated. In one embodiment, vehicle 100 is configured with one or more semi-autonomous operational modes in which one or more computing systems perform a portion of the navigation/maneuvering of the vehicle along a travel route, and a vehicle operator (i.e., driver) provides inputs to the vehicle to perform a portion of the navigation/maneuvering of vehicle 100 along a travel route.

Vehicle 100 may include one or more processors 110. In one or more arrangements, processor(s) 110 may be a main processor of vehicle 100. For instance, processor(s) 110 may be an electronic control unit (ECU). Vehicle 100 may include one or more data stores 115 for storing one or more types of data. Data store(s) 115 may include volatile memory, non-volatile memory, or both. Examples of suitable data store(s) 115 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. Data store(s) 115 may be a component of processor(s) 110, or data store 115 may be operatively connected to processor(s) 110 for use thereby. The term “operatively connected,” as used throughout this description, may include direct or indirect connections, including connections without direct physical contact.

In one or more arrangements, data store(s) 115 may include map data 116. Map data 116 may include maps of one or more geographic areas. In some instances, map data 116 may include information or data on roads, traffic control devices, road markings, structures, features, landmarks, or any combination thereof in the one or more geographic areas. Map data 116 may be in any suitable form. In some instances, map data 116 may include aerial views of an area. In some instances, map data 116 may include ground views of an area, including 360-degree ground views. Map data 116 may include measurements, dimensions, distances, information, or any combination thereof for one or more items included in map data 116. Map data 116 may also include measurements, dimensions, distances, information, or any combination thereof relative to other items included in map data 116. Map data 116 may include a digital map with information about road geometry. Map data 116 may be high quality, highly detailed, or both.

In one or more arrangements, map data 116 may include one or more terrain maps 117. Terrain map(s) 117 may include information about the ground, terrain, roads, surfaces, other features, or any combination thereof of one or more geographic areas. Terrain map(s) 117 may include elevation data in the one or more geographic areas. Terrain map(s) 117 may be high quality, highly detailed, or both. Terrain map(s) 117 may define one or more ground surfaces, which may include paved roads, unpaved roads, land, and other things that define a ground surface.

In one or more arrangements, map data 116 may include one or more static obstacle maps 118. Static obstacle map(s) 118 may include information about one or more static obstacles located within one or more geographic areas. A “static obstacle” is a physical object whose position does not change or substantially change over a period of time and whose size does not change or substantially change over a period of time. Examples of static obstacles include trees, buildings, curbs, fences, railings, medians, utility poles, statues, monuments, signs, benches, furniture, mailboxes, large rocks, hills. The static obstacles may be objects that extend above ground level. The one or more static obstacles included in static obstacle map(s) 118 may have location data, size data, dimension data, material data, other data, or any combination thereof, associated with it. Static obstacle map(s) 118 may include measurements, dimensions, distances, information, or any combination thereof for one or more static obstacles. Static obstacle map(s) 118 may be high quality, highly detailed, or both. Static obstacle map(s) 118 may be updated to reflect changes within a mapped area.

Data store(s) 115 may include sensor data 119. In this context, “sensor data” means any information about the sensors that vehicle 100 is equipped with, including the capabilities and other information about such sensors. As will be explained below, vehicle 100 may include sensor system 120. Sensor data 119 may relate to one or more sensors of sensor system 120. As an example, in one or more arrangements, sensor data 119 may include information on one or more LIDAR sensors 124 of sensor system 120.

In some instances, at least a portion of map data 116 or sensor data 119 may be located in data stores(s) 115 located onboard vehicle 100. Alternatively, or in addition, at least a portion of map data 116 or sensor data 119 may be located in data stores(s) 115 that are located remotely from vehicle 100.

As noted above, vehicle 100 may include sensor system 120. Sensor system 120 may include one or more sensors. “Sensor” means any device, component, or system that may detect or sense something. The one or more sensors may be configured to sense, detect, or perform both in real-time. As used herein, the term “real-time” means a level of processing responsiveness that a user or system senses as sufficiently immediate for a particular process or determination to be made, or that enables the processor to keep up with some external process.

In arrangements in which sensor system 120 includes a plurality of sensors, the sensors may work independently from each other. Alternatively, two or more of the sensors may work in combination with each other. In such an embodiment, the two or more sensors may form a sensor network. Sensor system 120, the one or more sensors, or both may be operatively connected to processor(s) 110, data store(s) 115, another element of vehicle 100 (including any of the elements shown in FIG. 1), or any combination thereof. Sensor system 120 may acquire data of at least a portion of the external environment of vehicle 100 (e.g., nearby vehicles).

Sensor system 120 may include any suitable type of sensor. Various examples of different types of sensors will be described herein. However, it will be understood that the embodiments are not limited to the particular sensors described. Sensor system 120 may include one or more vehicle sensors 121. Vehicle sensor(s) 121 may detect, determine, sense, or acquire in a combination thereof information about vehicle 100 itself. In one or more arrangements, vehicle sensor(s) 121 may be configured to detect, sense, or acquire in a combination thereof position and orientation changes of vehicle 100, such as, for example, based on inertial acceleration. In one or more arrangements, vehicle sensor(s) 121 may include one or more accelerometers, one or more gyroscopes, an inertial measurement unit (IMU), a dead-reckoning system, a global navigation satellite system (GNSS), a global positioning system (GPS), a navigation system 147, other suitable sensors, or any combination thereof. Vehicle sensor(s) 121 may be configured to detect, sense, or acquire in a combination thereof one or more characteristics of vehicle 100. In one or more arrangements, vehicle sensor(s) 121 may include a speedometer to determine a current speed of vehicle 100.

Alternatively, or in addition, sensor system 120 may include one or more environment sensors 122 configured to acquire, sense, or acquire in a combination thereof driving environment data. “Driving environment data” includes data or information about the external environment in which an autonomous vehicle is located or one or more portions thereof. For example, environment sensor(s) 122 may be configured to detect, quantify, sense, or acquire in any combination thereof obstacles in at least a portion of the external environment of vehicle 100, information/data about such obstacles, or a combination thereof. Such obstacles may be comprised of stationary objects, dynamic objects, or a combination thereof. Environment sensor(s) 122 may be configured to detect, measure, quantify, sense, or acquire in any combination thereof other things in the external environment of vehicle 100, such as, for example, lane markers, signs, traffic lights, traffic signs, lane lines, crosswalks, curbs proximate to vehicle 100, off-road objects, etc.

Various examples of sensors of sensor system 120 will be described herein. The example sensors may be part of the one or more environment sensor(s) 122, the one or more vehicle sensors 121, or both. However, it will be understood that the embodiments are not limited to the particular sensors described.

As an example, in one or more arrangements, sensor system 120 may include one or more radar sensors 123, one or more LIDAR sensors 124, one or more sonar sensors 125, one or more cameras 126, or any combination thereof. In one or more arrangements, camera(s) 126 may be high dynamic range (HDR) cameras or infrared (IR) cameras.

Vehicle 100 may include an input system 130. An “input system” includes any device, component, system, element or arrangement or groups thereof that enable information/data to be entered into a machine. Input system 130 may receive an input from a vehicle passenger (e.g., a driver or a passenger). Vehicle 100 may include an output system 135. An “output system” includes any device, component, or arrangement or groups thereof that enable information/data to be presented to a vehicle passenger (e.g., a person, a vehicle passenger, etc.).

Vehicle 100 may include one or more vehicle systems 140. Various examples of vehicle system(s) 140 are shown in FIG. 1. However, vehicle 100 may include more, fewer, or different vehicle systems. It should be appreciated that although particular vehicle systems are separately defined, each or any of the systems or portions thereof may be otherwise combined or segregated via hardware, software, or a combination thereof within vehicle 100. Vehicle 100 may include a propulsion system 141, a braking system 142, a steering system 143, throttle system 144, a transmission system 145, a signaling system 146, a navigation system 147, other systems, or any combination thereof. Each of these systems may include one or more devices, components, or combinations thereof, now known or later developed.

Navigation system 147 may include one or more devices, applications, or combinations thereof, now known or later developed, configured to determine the geographic location of the vehicle 100, to determine a travel route for vehicle 100, or to determine both. Navigation system 147 may include one or more mapping applications to determine a travel route for vehicle 100. Navigation system 147 may include a global positioning system, a local positioning system, a geolocation system, or any combination thereof.

Processor(s) 110, testbench system 170, automated driving module(s) 160, or any combination thereof may be operatively connected to communicate with various aspects of vehicle system(s) 140 or individual components thereof. For example, returning to FIG. 1, processor(s) 110, automated driving module(s) 160, or a combination thereof may be in communication to send or receive information from various aspects of vehicle system(s) 140 to control the movement, speed, maneuvering, heading, direction, etc. of vehicle 100. Processor(s) 110, testbench system 170, automated driving module(s) 160, or any combination thereof may control some or all of these vehicle system(s) 140 and, thus, may be partially or fully autonomous.

Processor(s) 110, testbench system 170, automated driving module(s) 160, or any combination thereof may be operable to control at least one of the navigation or maneuvering of vehicle 100 by controlling one or more of vehicle systems 140 or components thereof. For instance, when operating in an autonomous mode, processor(s) 110, testbench system 170, automated driving module(s) 160, or any combination thereof may control the direction, speed, or both of vehicle 100. Processor(s) 110, testbench system 170, automated driving module(s) 160, or any combination thereof may cause vehicle 100 to accelerate (e.g., by increasing the supply of fuel provided to the engine), decelerate (e.g., by decreasing the supply of fuel to the engine, by applying brakes), change direction (e.g., by turning the front two wheels), or perform any combination thereof. As used herein, “cause” or “causing” means to make, force, compel, direct, command, instruct, enable, or in any combination thereof an event or action to occur or at least be in a state where such event or action may occur, either in a direct or indirect manner.

Vehicle 100 may include one or more actuators 150. Actuator(s) 150 may be any element or combination of elements operable to modify, adjust, alter, or in any combination thereof one or more of vehicle systems 140 or components thereof to responsive to receiving signals or other inputs from processor(s) 110, automated driving module(s) 160, or a combination thereof. Any suitable actuator may be used. For instance, actuator(s) 150 may include motors, pneumatic actuators, hydraulic pistons, relays, solenoids, and piezoelectric actuators, just to name a few possibilities.

Vehicle 100 may include one or more modules, at least some of which are described herein. The modules may be implemented as computer-readable program code that, when executed by processor(s) 110, implement one or more of the various processes described herein. One or more of the modules may be a component of processor(s) 110, or one or more of the modules may be executed on or distributed among other processing systems to which processor(s) 110 is operatively connected. The modules may include instructions (e.g., program logic) executable by processor(s) 110. Alternatively, or in addition, data store(s) 115 may contain such instructions.

In one or more arrangements, one or more of the modules described herein may include artificial or computational intelligence elements, e.g., neural network, fuzzy logic, or other machine learning algorithms. Further, in one or more arrangements, one or more of the modules may be distributed among a plurality of the modules described herein. In one or more arrangements, two or more of the modules described herein may be combined into a single module.

Vehicle 100 may include one or more autonomous driving modules 160. Automated driving module(s) 160 may be configured to receive data from sensor system 120 or any other type of system capable of capturing information relating to vehicle 100, the external environment of the vehicle 100, or a combination thereof. In one or more arrangements, automated driving module(s) 160 may use such data to generate one or more driving scene models. Automated driving module(s) 160 may determine position and velocity of vehicle 100. Automated driving module(s) 160 may determine the location of obstacles, obstacles, or other environmental features including traffic signs, trees, shrubs, neighboring vehicles, pedestrians, etc.

Automated driving module(s) 160 may be configured to receive, determine, or in a combination thereof location information for obstacles within the external environment of vehicle 100, which may be used by processor(s) 110, one or more of the modules described herein, or any combination thereof to estimate: a position or orientation of vehicle 100; a vehicle position or orientation in global coordinates based on signals from a plurality of satellites or other geolocation systems; or any other data/signals that could be used to determine a position or orientation of vehicle 100 with respect to its environment for use in either creating a map or determining the position of vehicle 100 in respect to map data.

Automated driving module(s) 160 either independently or in combination with testbench system 170 may be configured to determine travel path(s), current autonomous driving maneuvers for vehicle 100, future autonomous driving maneuvers, modifications to current autonomous driving maneuvers, etc. Such determinations by automated driving module(s) 160 may be based on data acquired by sensor system 120, driving scene models, data from any other suitable source such as determinations from sensor data 250, or any combination thereof. In general, automated driving module(s) 160 may function to implement different levels of automation, including advanced driving assistance (ADAS) functions, semi-autonomous functions, and fully autonomous functions. “Driving maneuver” means one or more actions that affect the movement of a vehicle. Examples of driving maneuvers include accelerating, decelerating, braking, turning, moving in a lateral direction of vehicle 100, changing travel lanes, merging into a travel lane, and reversing, just to name a few possibilities. Automated driving module(s) 160 may be configured to implement driving maneuvers. Automated driving module(s) 160 may cause, directly or indirectly, such autonomous driving maneuvers to be implemented. As used herein, “cause” or “causing” means to make, command, instruct, enable, or in any combination thereof an event or action to occur or at least be in a state where such event or action may occur, either in a direct or indirect manner. Automated driving module(s) 160 may be configured to execute various vehicle functions, whether individually or in combination, to transmit data to, receive data from, interact with, or to control vehicle 100 or one or more systems thereof (e.g., one or more of vehicle systems 140).

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-14, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, or processes described above may be realized in hardware or a combination of hardware and software and may be realized in a centralized fashion in one processing system or in a distributed fashion where different elements are spread across several interconnected processing systems. Any kind of processing system or another apparatus adapted for carrying out the methods described herein is suited. A typical combination of hardware and software may be a processing system with computer-usable program code that, when being loaded and executed, controls the processing system such that it carries out the methods described herein. The systems, components, or processes also may be embedded in a computer-readable storage, such as a computer program product or other data programs storage device, readable by a machine, tangibly embodying a program of instructions executable by the machine to perform methods and processes described herein. These elements also may be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that may contain or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™ Smalltalk, C++, or the like and conventional procedural programming languages, such as the “C” programming language or similar programming languages. The program code may execute entirely on a user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein may be embodied in other forms without departing from the spirit or essential attributes thereof. Accordingly, reference should be made to the following claims, rather than to the foregoing specification, as indicating the scope hereof.

What is claimed is:

1. A system, comprising:
a processor; and
a memory communicably coupled to the processor and storing machine-readable instructions that, when executed by the processor, cause the processor to:
provide a vehicular testbench capable of operating physical and virtual vehicular components;
receive a test plan for a set of vehicular components;
determine testbench components and testbench connections including any virtual components to implement the test plan on the vehicular testbench;
generate the virtual components to perform the test plan; and
implement the testbench connections to enable testing of the vehicular components.

2. The system of claim 1, wherein to implement the testbench connections includes duplicating any testbench signals.

3. The system of claim 1, wherein to implement the testbench connections includes generating simulated testbench signals.

4. The system of claim 1, wherein the instructions further include to:
configure the vehicular testbench to support testing of a new component upon its connection to the vehicular testbench.

5. The system of claim 4, wherein to configure the vehicular testbench to support testing of the new component includes implementing an HMI rule to translate HMI signals in relation to the new component.

6. The system of claim 1, wherein the instructions further include to:
determine a first set of vehicular components to perform closed-loop testing and a second set of vehicular components to perform open-loop testing.

7. The system of claim 1, wherein the instructions further include to:
determine a first set of vehicular components to perform closed-loop testing and a second set of vehicular components to perform simulated closed-loop testing.

8. A non-transitory computer-readable medium including instructions that when executed by one or more processors cause the one or more processors to:
provide a vehicular testbench capable of operating physical and virtual vehicular components;
receive a test plan for a set of vehicular components;
determine testbench components and testbench connections including any virtual components to implement the test plan on the vehicular testbench;
generate the virtual components to perform the test plan; and
implement the testbench connections to enable testing of the vehicular components.

9. The non-transitory computer-readable medium of claim 8, wherein to implement the testbench connections includes duplicating any testbench signals.

10. The non-transitory computer-readable medium of claim 8, wherein to implement the testbench connections includes generating simulated testbench signals.

11. The non-transitory computer-readable medium of claim 8, wherein the instructions further include to:
configure the vehicular testbench to support testing of a new component upon its connection to the vehicular testbench.

12. The non-transitory computer-readable medium of claim 11, wherein to configure the vehicular testbench to support testing of the new component includes implementing an HMI rule to translate HMI signals in relation to the new component.

13. The non-transitory computer-readable medium of claim 8, wherein the instructions further include to:
determine a first set of vehicular components to perform closed-loop testing and a second set of vehicular components to perform open-loop testing.

14. A method, comprising:
providing a vehicular testbench capable of operating physical and virtual vehicular components;
receiving a test plan for a set of vehicular components;
determining testbench components and testbench connections including any virtual components to implement the test plan on the vehicular testbench;
generating the virtual components to perform the test plan; and
implementing the testbench connections to enable testing of the vehicular components.

15. The method of claim 14, wherein implementing the testbench connections includes duplicating any testbench signals.

16. The method of claim 14, wherein implementing the testbench connections includes generating simulated testbench signals.

17. The method of claim 14, further comprising:
configuring the vehicular testbench to support testing of a new component upon its connection to the vehicular testbench.

18. The method of claim 17, wherein configuring the vehicular testbench to support testing of the new component includes implementing an HMI rule to translate HMI signals in relation to the new component.

19. The method of claim 14, further comprising:
determining a first set of vehicular components to perform closed-loop testing and a second set of vehicular components to perform open-loop testing.

20. The method of claim 14, further comprising:
determining a first set of vehicular components to perform closed-loop testing and a second set of vehicular components to perform simulated closed-loop testing.
